(19) United States
(12) Patent Application Publication
(10) Pub. No.: US 2024/0332343 A1
(43) Pub. Date: Oct. 3, 2024

(54) REDUCING CROSSTALK AND IMPROVING CONTRAST IN LED AND PCLED ARRAYS

(71) Applicant: LUMILEDS LLC, San Jose, CA (US)

(72) Inventors: Yu-Chen Shen, Sunnyvale, CA (US); Rohit Modi, San Jose, CA (US); Gregoire Denis, San Jose, CA (US)

(73) Assignee: LUMILEDS LLC, San Jose, CA (US)

(21) Appl. No.: 18/742,116

(22) Filed: Jun. 13, 2024

Related U.S. Application Data
(63) Continuation of application No. PCT/US2022/051257, filed on Nov. 29, 2022.
(60) Provisional application No. 63/289,857, filed on Dec. 15, 2021.

(51) Int. Cl. H01L 27/15; H01L 25/075; H01L 33/50

(52) U.S. Cl. CPC H01L 27/156; H01L 25/0753; H01L 33/502; H01L 33/505

(57) ABSTRACT

A light emitting device comprises at least two semiconductor LEDs arranged in an array with each semiconductor LED comprising a light emitting surface with boundaries defined by a perimeter, a continuous layer comprising a first surface through which light is emitted from the light emitting device during operation and an oppositely positioned second surface disposed on or adjacent to the array and extending over the light emitting surfaces of the semiconductor LEDs, and a plurality of optical isolation structures arranged in the continuous layer in a discontinuous manner along the perimeters of the light emitting surfaces between adjacent LEDs in the array.

### CROSS-REFERENCE TO RELATED APPLICATIONS

This application is a continuation of PCT Application PCT/US2022/051257 filed Nov. 29, 2022, which claims benefit of priority to U.S. Provisional Patent Application No. 63/289,857 filed Dec. 15, 2021. Both of the above applications are incorporated herein by reference in their entirety.

### FIELD OF THE INVENTION

The invention relates generally to LED and pcLED arrays.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Inorganic LEDs and pcLEDs have been widely used to create different types of displays, matrices and light engines including automotive adaptive headlights, augmented-reality (AR) displays, virtual-reality (VR) displays, mixed-reality (MR) displays (AR, VR, and MR systems referred to herein as visualization systems), smart glasses and displays for mobile phones, smart watches, monitors and TVs, and flash illumination for cameras in mobile phones. Individual LEDs or pcLEDs in these architectures can have an area of a few square millimeters down to a few square micrometers (e.g., microLEDs) depending on the matrix or display sized and its pixel per inch requirements.

One of the key specifications for LED and pcLED arrays is the crosstalk ratio (CR). CR is defined as the luminance ratio of one or a group of “ON” state pixel(s) vs. adjacent “OFF” state pixels. The crosstalk ratio is greatly degraded when photons spill from an “ON” state pixel to neighboring “OFF” state pixels. Low CR typically results in blurry images or compromised projected beam patterns, for example. Contrast is defined as the luminance drop-off perpendicular to the border of an on pixel and an off pixel.

### SUMMARY

This specification discloses light emitting devices comprising at least two semiconductor LEDs arranged in an array with each semiconductor LED comprising a light emitting surface, a continuous layer (e.g., a continuous wavelength converting layer) comprising a first surface through which light is emitted from the light emitting device during operation and an oppositely positioned second surface disposed on or adjacent to the array and extending over the light emitting surfaces of the semiconductor LEDs, and a plurality of optical isolation structures arranged in the continuous layer along the perimeters of the light emitting surfaces between adjacent LEDs in the array.

The optical isolation structures are arranged discontinuously along the perimeters of the light emitting surfaces of the LEDs. That is, there are portions of the perimeter of each LED light emitting surface in which no optical isolation structure is present. This differs from an arrangement in which an optical isolation structure runs continuously along the perimeter of the LED light emitting surface, all the way around the light emitting surface.

Optical isolation structures generally cause some loss of light output from the device, either by directly absorbing light incident on the structure or by redirecting some of the light incident on the structure toward a light absorbing portion of the device. Arranging the optical isolation structures discontinuously around the perimeters of the light emitting surfaces of the LEDs, as taught herein, reduces crosstalk and increases contrast between adjacent pixels in the array, while increasing light output from the device compared to a device in which a continuous optical isolation structure surrounds the perimeter of each LED light emitting surface.

In the device described above, the array may be a monolithic array, for example a monolithic microLED array.

As noted above, the continuous layer may be or comprise a wavelength converting material that absorbs primary light emitted by the semiconductor LEDs and in response emits secondary light. In such cases the continuous layer may be or comprise, for example, a ceramic phosphor layer or a layer of phosphor particles disposed in a matrix.

Alternatively, the continuous layer may be or comprises a material transparent to light emitted by the semiconductor LEDs. In such cases the continuous layer may be or comprise, for example, GaN or sapphire.

The optical isolation structures may comprise, for example, absorptive material (e.g., pigments), reflective material (e.g., reflective metals), light scattering material (e.g., light scattering particles dispersed in a binder), and/or materials (e.g., air) having an index of refraction for visible light lower than that of the continuous layer.

The optical isolation structures may, for example, have the form of elongated channels (e.g., of rectangular, u-shape, or v-shape cross-section) in the continuous layer extending along the perimeter of a light emitting surface or of channels (e.g., of cylindrical or any other suitable cross-section) primarily directed into the continuous layer and not appreciably elongated along a perimeter of a light emitting surface.

The optical isolation structures may be spaced uniformly or nonuniformly along the perimeters of the light emitting surfaces.

The optical isolation structures may penetrate entirely through the continuous layer, penetrate from the first surface of the continuous layer into but not entirely through the continuous layer, or penetrate from the second surface of the continuous layer into but not entirely through the continuous layer.

In some variations, the perimeter of each light emitting surface comprises three or more sides that intersect at vertices. In some of these variations, at least one optical isolation structure is approximately centered between adjacent vertices along each side and elongated parallel to the perimeter without extending along the entire length of the side.

An illumination system may comprise a light emitting device of any of the variations described above, and an optic or optical system arranged to image the array to form an output illumination beam. In some variations, at least some of the semiconductor LEDs are independently operable to steer a direction of the output illumination beam.

A display system may comprise a light emitting device of any of the variations described above, a display, and an optic or optical system arranged to couple light from the light source into the display.

A mobile device may comprise a camera, a flash illumination system, and a controller. The flash illumination system may comprise a light emitting device of any of the variations described above, and an optic or optical system arranged to at least partially collimate light emitted by the light source. The controller may be configured to operate the semiconductor LEDs in the light emitting device to match a field of view of the flash illumination system to a field of view of the camera.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system.

FIG. 6 schematically illustrates an example display (e.g., AR/VR/MR) system.

FIG. 7 shows a block diagram of an example visualization system.

FIG. 8 shows a schematic cross-sectional view of a light emitting device comprising an LED array that illustrates crosstalk between adjacent pixels in the device.

FIGS. 9A, 9B, and 9C show schematic cross-sectional views of example light emitting devices comprising LED arrays and optical isolation structures as described herein.

FIGS. 9D, 9E, 9F, 9G, 9H, and 9I show schematic top views of example light emitting devices as in FIGS. 9A, 9B, and 9C.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

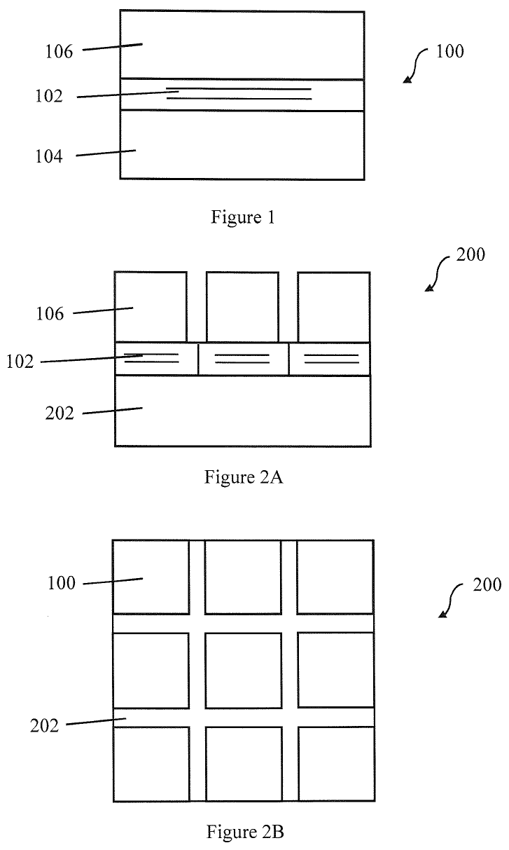

FIG. 1 shows an example of an individual pcLED 100 comprising a light emitting semiconductor diode (LED) structure 102 disposed on a substrate 104, and a phosphor layer 106 (which may also be referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. Phosphor layers may for example comprise phosphor particles dispersed in or bound to each other with a binder material or be or comprise a sintered ceramic phosphor plate.

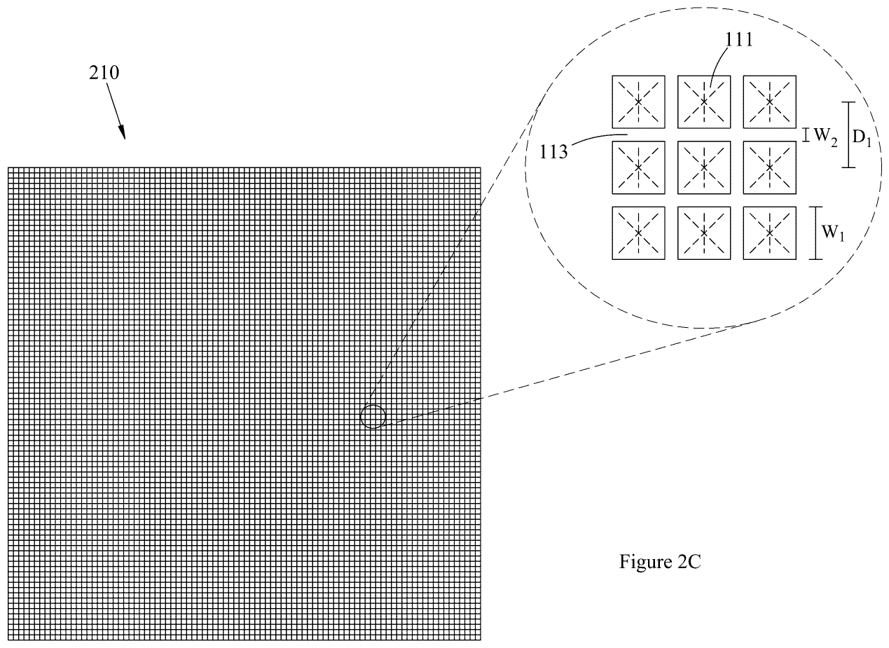

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of LEDs or pcLEDs may be formed from individual mechanically separate LEDs or pcLEDs. Substrate 202 may optionally comprise CMOS circuitry for driving the LEDs and may be formed from any suitable materials.

Although FIGS. 2A-2B show a three-by-three array of nine pcLEDs, such arrays may include for example tens, hundreds, or thousands of LEDs or pcLEDs. Individual LEDs or pcLEDs may have widths (e.g., side lengths) in the plane of the array of, for example, less than or equal to 1 millimeter (mm), less than or equal to 500 microns, less than or equal to 100 microns, less than or equal to 50 microns, or less than or equal to 10 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W₁ are arranged as a square matrix with neighboring LEDs or pcLEDs having a center-to-center distances D₁ and separated by lanes 113 having a width W₂. W₁ may be, for example, less than or equal to 1 millimeter (mm), less than or equal to 500 microns, less than or equal to 100 microns, less than or equal to 50 microns, or less than or equal to 10 microns. W₂ may be, for example, hundreds of microns, less than or equal to 100 microns, less than or equal to 50 microns, less than or equal to 10 microns, or less than or equal to 5 microns. D₁=W₁+W₂.

An array may be formed, for example, by dicing wafer 210 into individual LEDs or pcLEDs and arranging the dice on a substrate. Alternatively, an array may be formed from the entire wafer 210, or by dividing wafer 210 into smaller arrays of LEDs or pcLEDs.

LEDs or pcLEDs having dimensions in the plane of the array (e.g., side lengths) of less than or equal to about 50 microns are typically referred to as microLEDs, and an array of such microLEDs may be referred to as a microLED array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated or partially electrically isolated from each other by trenches and/or insulating material, but the electrically isolated or partially electrically isolated segments remain physically connected to each other by other portions of the semiconductor structure. For example, in such a monolithic structure the active region and a first semiconductor layer of a first conductivity type (n or p) on one side of the active region may be segmented, and a second unsegmented semiconductor layer of the opposite conductivity type (p or n) positioned on the opposite side of the active region from the first semiconductor layer. The second semiconductor layer may then physically and electrically connect the segmented structures to each other on one side of the active region, with the segmented structures otherwise electrically isolated from each other and thus separately operable as individual LEDs.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

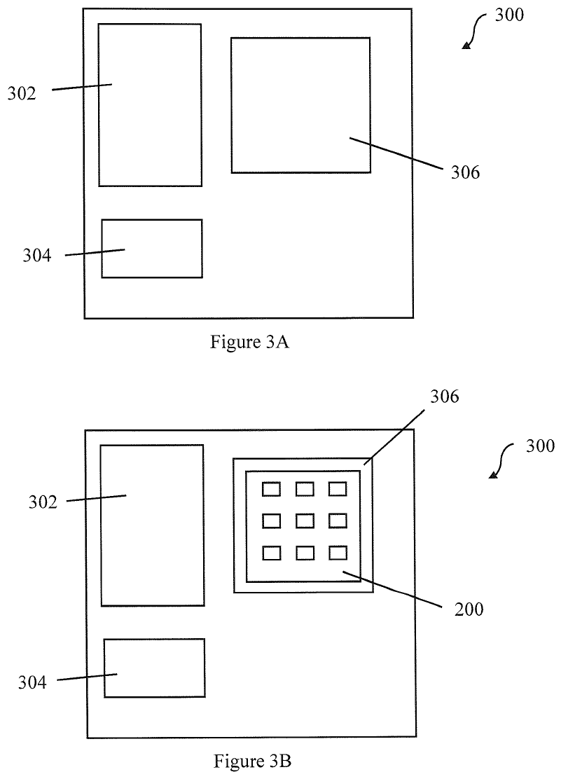

As shown in FIGS. 3A-3B, an LED or pcLED array 200 may for example be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

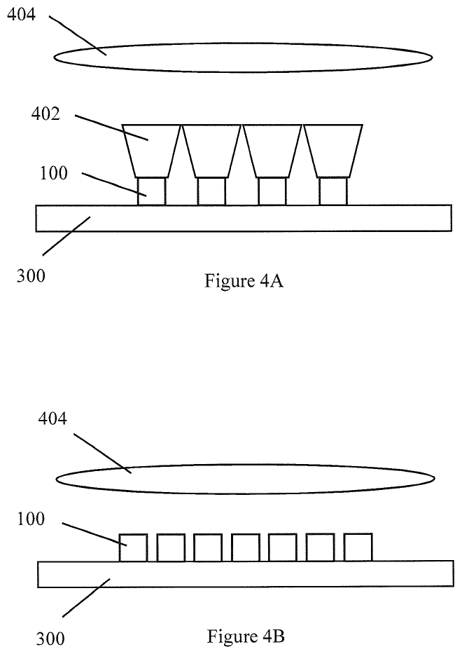

Individual LEDs or pcLEDs may optionally incorporate or be arranged in combination with a lens or other optical element located adjacent to or disposed on the LED or the phosphor layer of the pcLED. Such an optical element, not shown in the figures, may be referred to as a “primary optical element”. In addition, as shown in FIGS. 4A-4B an array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when LEDs or pcLEDs can be spaced sufficiently close to each other and may also be used in automobile headlights as well as in camera flash applications. A microLED display application may use similar optical arrangements to those depicted in FIGS. 4A-4B, for example.

In another example arrangement, a central block of LEDs or pcLEDs in an array may be associated with a single common (shared) optic, and edge LEDs or pcLEDs located in the array at the periphery of the central bloc are each associated with a corresponding individual optic.

Generally, any suitable arrangement of optical elements may be used in combination with the LED and pcLED arrays described herein, depending on the desired application.

LED and pcLED arrays as described herein may be useful for applications requiring or benefiting from fine-grained intensity, spatial, and temporal control of light distributions. These applications may include, but are not limited to, precise special patterning of emitted light from individual LEDs or pcLEDs or from groups (e.g., blocks) of LEDs or pcLEDs. Depending on the application, emitted light may be spectrally distinct, adaptive over time, and/or environmentally responsive. Such arrays may provide pre-programmed light distribution in various intensity, spatial, or temporal patterns. The emitted light may be based at least in part on received sensor data and may be used for optical wireless communications. Associated electronics and optics may be distinct at an individual LED/pcLED, group, or device level.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g, adaptive headlights), mobile device camera (e.g., adaptive flash), AR, VR, and MR applications such as those described below.

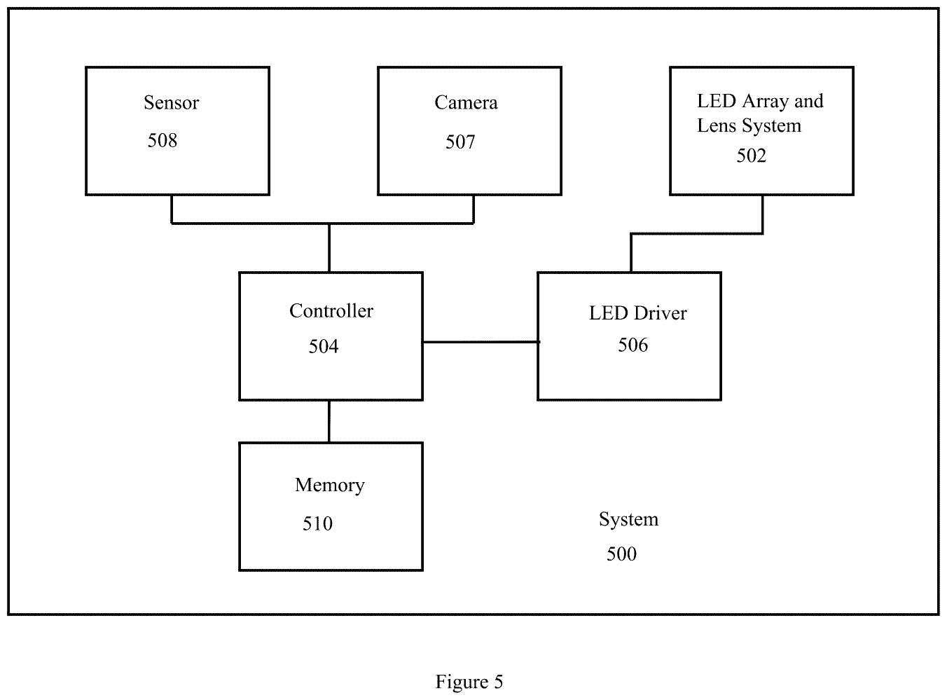

FIG. 5 schematically illustrates an example camera flash system 500 comprising an LED or pcLED array and an optical (e.g., lens) system 502, which may be or comprise an adaptive lighting system as described above in which LEDs or pcLEDs in the array may be individually operable or operable as groups. In operation of the camera flash system, illumination from some or all of the LEDs or pcLEDs in array and optical system 502 may be adjusted-deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

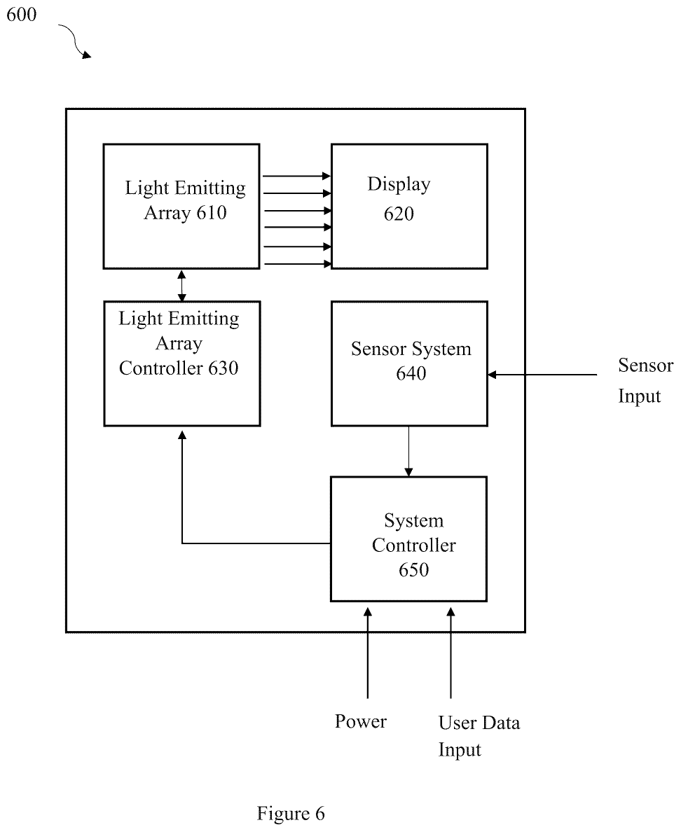

FIG. 6 schematically illustrates an example display system 600 that includes an array 610 of LEDs or pcLEDs that are individually operable or operable in groups, a display 620, a light emitting array controller 630, a sensor system 640, and a system controller 650. Array 610 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Similarly, to provide redundancy in the event of a defective LED or pcLED, a group of six individually operable adjacent LEDs or pcLEDs comprising two red emitters, two blue emitters, and two green emitters may correspond to a single color-tunable pixel in the display Array 610 can be used to project light in graphical or object patterns that can for example support AR/VR/MR systems.

Sensor input is provided to the sensor system 640, while power and user data input is provided to the system controller 650. In some embodiments modules included in system 600 can be compactly arranged in a single structure, or one or more elements can be separately mounted and connected via wireless or wired communication. For example, array 610, display 620, and sensor system 640 can be mounted on a headset or glasses, with the light emitting array controller and/or system controller 650 separately mounted.

System 600 can incorporate a wide range of optics (not shown) to couple light emitted by array 610 into display 620. Any suitable optics may be used for this purpose.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input through the sensor system can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

As noted above, AR, VR, and MR systems may be more generally referred to as examples of visualization systems. In a virtual reality system, a display can present to a user a view of a scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

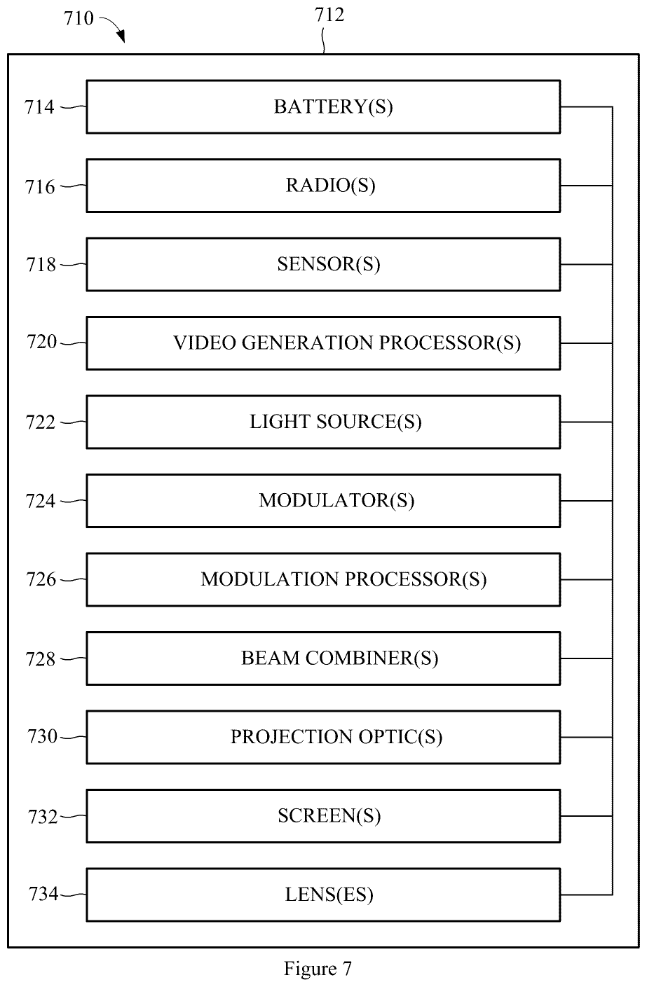

FIG. 7 shows a generalized block diagram of an example visualization system 710. The visualization system 710 can include a wearable housing 712, such as a headset or goggles. The housing 712 can mechanically support and house the elements detailed below. In some examples, one or more of the elements detailed below can be included in one or more additional housings that can be separate from the wearable housing 712 and couplable to the wearable housing 712 wirelessly and/or via a wired connection. For example, a separate housing can reduce the weight of wearable goggles, such as by including batteries, radios, and other elements. The housing 712 can include one or more batteries 714, which can electrically power any or all of the elements detailed below. The housing 712 can include circuitry that can electrically couple to an external power supply, such as a wall outlet, to recharge the batteries 714. The housing 712 can include one or more radios 716 to communicate wirelessly with a server or network via a suitable protocol, such as WiFi.

The visualization system 710 can include one or more sensors 718, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 718 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 718 can capture a real-time video image of the surroundings proximate a user.

The visualization system 710 can include one or more video generation processors 720. The one or more video generation processors 720 can receive, from a server and/or a storage medium, scene data that represents a three-dimensional scene, such as a set of position coordinates for objects in the scene or a depth map of the scene. The one or more video generation processors 720 can receive one or more sensor signals from the one or more sensors 718. In response to the scene data, which represents the surroundings, and at least one sensor signal, which represents the location and/or orientation of the user with respect to the surroundings, the one or more video generation processors 720 can generate at least one video signal that corresponds to a view of the scene. In some examples, the one or more video generation processors 720 can generate two video signals, one for each eye of the user, that represent a view of the scene from a point of view of the left eye and the right eye of the user, respectively. In some examples, the one or more video generation processors 720 can generate more than two video signals and combine the video signals to provide one video signal for both eyes, two video signals for the two eyes, or other combinations.

The visualization system 710 can include one or more light sources 722 that can provide light for a display of the visualization system 710. Suitable light sources 722 can include any of the LEDs, pcLEDs, LED arrays, and pcLED arrays discussed above, for example those discussed above with respect to display system 600.

The visualization system 710 can include one or more modulators 724. The modulators 724 can be implemented in one of at least two configurations.

In a first configuration, the modulators 724 can include circuitry that can modulate the light sources 722 directly. For example, the light sources 722 can include an array of light-emitting diodes, and the modulators 724 can directly modulate the electrical power, electrical voltage, and/or electrical current directed to each light-emitting diode in the array to form modulated light. The modulation can be performed in an analog manner and/or a digital manner. In some examples, the light sources 722 can include an array of red light-emitting diodes, an array of green light-emitting diodes, and an array of blue light-emitting diodes, and the modulators 724 can directly modulate the red light-emitting diodes, the green light-emitting diodes, and the blue light-emitting diodes to form the modulated light to produce a specified image.

In a second configuration, the modulators 724 can include a modulation panel, such as a liquid crystal panel. The light sources 722 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 724 can include multiple modulation panels that can modulate different colors of light. For example, the modulators 724 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 724 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 710 can include one or more modulation processors 726, which can receive a video signal, such as from the one or more video generation processors 720, and, in response, can produce an electrical modulation signal. For configurations in which the modulators 724 directly modulate the light sources 722, the electrical modulation signal can drive the light sources 724. For configurations in which the modulators 724 include a modulation panel, the electrical modulation signal can drive the modulation panel.

The visualization system 710 can include one or more beam combiners 728 (also known as beam splitters 728), which can combine light beams of different colors to form a single multi-color beam. For configurations in which the light sources 722 can include multiple light-emitting diodes of different colors, the visualization system 710 can include one or more wavelength-sensitive (e.g., dichroic) beam splitters 728 that can combine the light of different colors to form a single multi-color beam.

The visualization system 710 can direct the modulated light toward the eyes of the viewer in one of at least two configurations. In a first configuration, the visualization system 710 can function as a projector, and can include suitable projection optics 730 that can project the modulated light onto one or more screens 732. The screens 732 can be located a suitable distance from an eye of the user. The visualization system 710 can optionally include one or more lenses 734 that can locate a virtual image of a screen 732 at a suitable distance from the eye, such as a close-focus distance, such as 500 mm, 750 mm, or another suitable distance. In some examples, the visualization system 710 can include a single screen 732, such that the modulated light can be directed toward both eyes of the user. In some examples, the visualization system 710 can include two screens 732, such that the modulated light from each screen 732 can be directed toward a respective eye of the user. In some examples, the visualization system 710 can include more than two screens 732. In a second configuration, the visualization system 710 can direct the modulated light directly into one or both eyes of a viewer. For example, the projection optics 730 can form an image on a retina of an eye of the user, or an image on each retina of the two eyes of the user.

For some configurations of augmented reality systems, the visualization system 710 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

As summarized above, this specification discloses light emitting devices that comprises at least two semiconductor LEDs arranged in an array with each semiconductor LED comprising a light emitting surface with boundaries defined by a perimeter, a continuous layer comprising a first surface through which light is emitted from the light emitting device during operation and an oppositely positioned second surface disposed on or adjacent to the array and extending over the light emitting surfaces of the semiconductor LEDs, and a plurality of optical isolation structures arranged in the continuous layer in a discontinuous manner along the perimeters of the light emitting surfaces between adjacent LEDs in the array.

These light emitting devices may comprise, or be components of, the apparatus, and devices, and systems described above with respect to FIGS. 1-7.

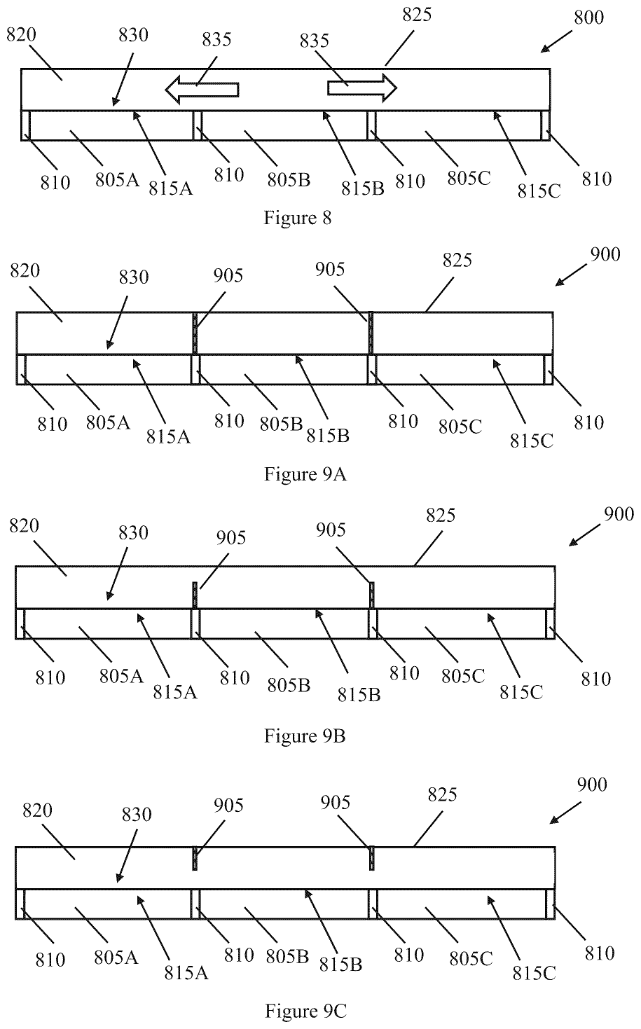

FIG. 8 shows a schematic cross-sectional view illustrating crosstalk between adjacent pixels in a light emitting device 800. In the figure, device 800 comprises a monolithic array of semiconductor LEDs 805A, 805B, and 805C electrically isolated from each other by trenches 810, which may comprise for example dielectric materials and/or electrical contacts to the individual LEDs in the array. The LEDs have top light emitting surfaces 815A, 815B, and 815C through which the LEDs emit light when in operation. Perimeters of the light emitting surfaces are formed by trenches 810.

Light emitting device 800 also comprises a continuous layer 820 having a first surface 825 through which light is emitted from the light emitting device during operation, and an oppositely positioned second surface 830 disposed on or adjacent to the array of LEDs and extending over the light emitting surfaces of the LEDs. Continuous layer 820 may be or comprise a layer of wavelength converting material, or alternatively be transparent to light emitted by the LEDs. In operation, the LEDs emit light through their top light emitting surfaces into the continuous layer.

As shown in FIG. 8 by arrows 835, light may be scattered laterally by the continuous layer from an operating pixel 805B toward adjacent pixels 805A and 805C. Light emitted from light emitting device may therefore appear to originate from pixels 805A and 805C even if they are not operating. This crosstalk reduces contrast between adjacent pixels.

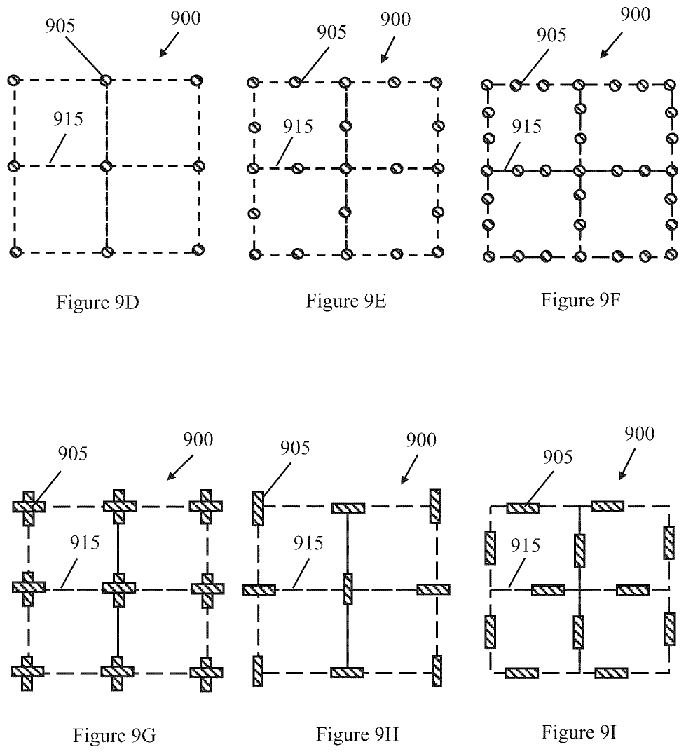

FIGS. 9A-9C show schematic cross-sectional views, and FIGS. 9D-9I show schematic top views, of light emitting devices comprising LED arrays in combination with a continuous layer similarly to device 800 shown in FIG. 8, and in addition comprising optical isolation structures disposed discontinuously along perimeters of the LEDs in the arrays as described above.

FIG. 9A shows in cross-section a light emitting device 900 in which optical isolation structures 905 penetrate entirely through the continuous layer. FIG. 9B shows in cross-section a light emitting device 900 in which optical isolation structures 905 penetrate from the continuous layer surface 830 nearest the LED array into but not entirely through the continuous layer. FIG. 9C shows in cross-section a light emitting device in which the optical isolation structure 905 penetrate from the continuous layer surface 825 opposite from the LED array into but not entirely through the continuous layer. Any suitable combination of optical isolation structures penetrating entirely or only partially through the continuous layer may be used.

It may be advantageous to use optical isolation structures that do not penetrate entirely through the continuous layer to the LED array, to avoid damage to the LED array.

FIGS. 9D-9I show top views of portions of light emitting devices 900 as shown in FIGS. 9A-9C, with optical isolation structures 905 disposed discontinuously along the perimeters (dashed lines) 915 of the individual LEDs (e.g., above the trenches 810 shown in FIG. 8). FIGS. 9D-9F schematically show optical isolation structures 905 as not appreciably elongated along the perimeters, in contrast to FIGS. 9G-9I which schematically show optical isolation structures 905 elongated along the perimeters.

The optical isolation function of optical isolation structures 905 may result, for example, form light absorbing, light reflecting, or light scattering material disposed in the optical isolation structures. Alternatively, the optical isolation function may result from reflection or scattering at an interface between the optical isolation structure and the continuous layer if the optical isolation structure comprises material having a refractive index less than or greater than that of the continuous layer.

In some variations, the semiconductor LEDs in the light emitting devices emit blue light, and the continuous layer comprises a wavelength converting material that absorbs blue light and in response emits secondary light of a longer wavelength. An unabsorbed portion of the blue light in combination with the secondary light may form a white light output from the device.

The semiconductor LED array may, for example, be a microLED array. In such cases the side lengths of the individual pixels may be, for example, about 1 micron to about 50 microns, or about 5 microns to about 50 microns, or about 10 microns to about 50 microns.

The optical isolation structures may be formed, for example, by laser ablation of the continuous layer material or by any other suitable method for removing material from the continuous layer. Light absorbing, light scattering, light reflecting, or low refractive index materials may subsequently be deposited by conventional methods into holes, trenches, or other suitable openings formed in the continuous layer. Examples of such materials include metals or dielectrics such as for example CaF₂, MgF₂, low refractive index polymers, and porous SiO₂. Alternatively, the openings may be left empty, except for containing air.

Alternatively, the optical isolation structures may be formed for example by printing (e.g., 3D printing) or otherwise depositing light absorbing, light scattering, light reflecting, or low refractive index material onto the LED array (e.g., above trenches that isolate LEDs in the array) and subsequently depositing the continuous layer on and/or around the optical isolation structures.

The optical isolations structures may have widths transverse to the perimeter of a light emitting surface of, for example, 20% or less the width of the light emitting surface. The optical isolation structures may penetrate through the continuous layer to a depth perpendicular to the LED light emitting surfaces of, for example, about 25%, about 50%, about 75%, or about 100% of the thickness of the continuous layer.

The following enumerated clauses provide additional non-limiting aspects of the disclosure.

1. A light emitting device comprising:
at least two semiconductor LEDs arranged in an array, each semiconductor LED comprising a light emitting surface with boundaries defined by a perimeter;
a continuous layer comprising a first surface through which light is emitted from the light emitting device during operation and an oppositely positioned second surface disposed on or adjacent to the array and extending over the light emitting surfaces of the semiconductor LEDs; and
a plurality of optical isolation structures arranged in the continuous layer in a discontinuous manner along the perimeters of the light emitting surfaces between adjacent LEDs in the array.

2 The light emitting device of clause 1, wherein the semiconductor LEDs are microLEDs.

3. The light emitting device of clause 1 or clause 2, wherein the array is monolithic.

4. The light emitting device of clauses 1-3, wherein the continuous layer comprises wavelength converting material that absorbs primary light emitted by the semiconductor LEDs and in response emits secondary light.

5. The light emitting device of clause 4, wherein the continuous layer is or comprises a ceramic phosphor layer.

6. The light emitting device of clause 4, wherein the continuous layer comprises phosphor particles disposed in a matrix.

7. The light emitting device of any of clauses 1-3, wherein the continuous layer is or comprises a material transparent to light emitted by the semiconductor LEDs.

8. The light emitting device of clause 7, wherein the continuous layer is or comprises GaN or sapphire.

9. The light emitting device of any of clauses 1-8, wherein the optical isolation structures comprise reflective material.

10. The light emitting device of any of clauses 1-8, wherein the optical isolation structures comprise light scattering material.

11. The light emitting device of any of clauses 1-8, wherein the optical isolation structures comprise material having an index of refraction lower than that of the continuous layer for visible light.

12. The light emitting device of any of any of clauses 1-11, wherein the optical isolation structures are elongated along the perimeters of the light emitting surfaces.

13. The light emitting device of any of clauses 1-12, wherein the optical isolation structures are spaced uniformly along the perimeters of the light emitting surfaces.

14. The light emitting device of any of clauses 1-12, wherein the optical isolation structures are spaced nonuniformly along the perimeters of the light emitting surfaces.

15. The light emitting device of any of clauses 1-14, wherein at least some of the optical isolation structures penetrate entirely through the continuous layer.

16. The light emitting device of any of clauses 1-14, wherein at least some of the optical isolation structures penetrate from the first surface of the continuous layer into but not entirely through the continuous layer.

17 The light emitting device of any of clauses 1-14, wherein at least some of the optical isolation structures penetrate from the second surface of the continuous layer into but not entirely through the continuous layer.

18. The light emitting device of any of clauses 1-17, wherein the perimeter comprises three or more sides intersecting at vertices, and at least one optical isolation structure is centered between adjacent vertices along each side.

19. An illumination system comprising:
a light emitting device as in any of clauses 1-18; and
an optic or optical system arranged to image the array to form an output illumination beam.

20. The illumination system of clause 19 wherein at least some of the semiconductor LEDs are independently operable to steer a direction of the output illumination beam.

21. A display system comprising:
a light emitting device as in any of clauses 1-18;
a display; and
an optic or optical system arranged to couple light from the light source into the display.

22. A mobile device comprising:
a camera;
a flash illumination system comprising the light emitting device of any of clauses 1-18 and an optic or optical system arranged to at least partially collimate light emitted by the light source; and
a controller configured to operate the semiconductor LEDs in the light emitting device to match a field of view of the flash illumination system to a field of view of the camera.

This disclosure is illustrative and not limiting. Further modifications will be apparent to one skilled in the art in light of this disclosure and are intended to fall within the scope of the appended claims.

What is claimed is:

1. A light emitting device comprising:
at least two semiconductor LEDs arranged in an array, each semiconductor LED comprising a light emitting surface with boundaries defined by a perimeter;
a continuous layer comprising a first surface through which light is emitted from the light emitting device during operation and an oppositely positioned second surface disposed on or adjacent to the array and extending over the light emitting surfaces of the semiconductor LEDs; and
a plurality of optical isolation structures arranged in the continuous layer in a discontinuous manner along the perimeters of the light emitting surfaces between adjacent LEDs in the array.

2. The light emitting device of claim 1, wherein the semiconductor LEDs are microLEDs.

3. The light emitting device of claim 1, wherein the array is monolithic.

4. The light emitting device of claim 1, wherein the continuous layer comprises wavelength converting material that absorbs primary light emitted by the semiconductor LEDs and in response emits secondary light.

5. The light emitting device of claim 4, wherein the continuous layer is or comprises a ceramic phosphor layer.

6. The light emitting device of claim 4, wherein the continuous layer comprises phosphor particles disposed in a matrix.

7. The light emitting device of claim 1, wherein the continuous layer is or comprises a material transparent to light emitted by the semiconductor LEDs.

8. The light emitting device of claim 7, wherein the continuous layer is or comprises GaN or sapphire.

9. The light emitting device of claim 1, wherein the optical isolation structures comprise reflective material.

10. The light emitting device of claim 1, wherein the optical isolation structures comprise light scattering material.

11. The light emitting device of claim 1, wherein the optical isolation structures comprise material having an index of refraction lower than that of the continuous layer for visible light.

12. The light emitting device of claim 1, wherein the optical isolation structures are spaced uniformly along the perimeters of the light emitting surfaces.

13. The light emitting device of claim 1, wherein the optical isolation structures are spaced nonuniformly along the perimeters of the light emitting surfaces.

14. The light emitting device of claim 1, wherein at least some of the optical isolation structures penetrate entirely through the continuous layer.

15. The light emitting device of claim 1, wherein at least some of the optical isolation structures penetrate from the first surface of the continuous layer into but not entirely through the continuous layer.

16. The light emitting device of claim 1, wherein at least some of the optical isolation structures penetrate from the second surface of the continuous layer into but not entirely through the continuous layer.

17. An illumination system comprising:
a light emitting device as in claim 1; and
an optic or optical system arranged to image the array to form an output illumination beam.

18. The illumination system of claim 17 wherein at least some of the semiconductor LEDs are independently operable to steer a direction of the output illumination beam.

19. A display system comprising:
a light emitting device as in claim 1;
a display; and
an optic or optical system arranged to couple light from the light source into the display.

20. A mobile device comprising:
a camera;
a flash illumination system comprising the light emitting device of claim 1 and an optic or optical system arranged to at least partially collimate light emitted by the light source; and
a controller configured to operate the semiconductor LEDs in the light emitting device to match a field of view of the flash illumination system to a field of view of the camera.
